(19) United States
(12) Patent Application Publication
(10) Pub. No.: US 2026/0277460 A1
(43) Pub. Date: Sep. 17, 2026

(54) VOLTAGE DROP MITIGATION USING DYNAMIC IDLE-TO-ACTIVE TRANSITIONS

(71) Applicant: ADVANCED MICRO DEVICES, INC., Santa Clara, CA (US)

(72) Inventors: Hideki Kanayama, Santa Clara, CA (US); Yubin Yao, Santa Clara, CA (US)

(21) Appl. No.: 19/079,094

(22) Filed: Mar. 13, 2025

(51) Int. Cl. G06F 3/06

(52) U.S. Cl. CPC G06F 3/0634; G06F 3/0613; G06F 3/0659; G06F 3/0673

(57) ABSTRACT

Techniques are provided for dynamically adjusting memory states in response to a density of received Column Address Strobe (CAS) memory commands. A memory controller monitors CAS command density over a configurable quantity of memory cycles in an idle memory state. If the CAS command density exceeds an idling threshold during the idle memory state, the memory subsystem selectively throttles CAS commands for a defined throttling duration to limit bandwidth and stabilize power demands, after which the memory subsystem transitions to a normal memory state in which all CAS commands are processed. If CAS command density subsequently falls below the idling threshold, the memory subsystem returns to the idle state.

### BACKGROUND

The adoption of advanced packaging technologies and multi-chiplet designs exacerbates the complexity of modern computer memory system implementation. Such architectures, while offering improved scalability and performance, pose significant challenges with respect to power delivery and thermal management.

One challenge in memory subsystem management is the management of power stability during transitions between different operational states. In particular, when memory subsystems transition from idle or low-activity states to high-bandwidth operational states, the sudden surge in power demand can result in voltage drops on the power delivery network. These voltage drops can lead to instability in the memory subsystem, causing degraded performance or, in severe cases, system failures.

Previous approaches to mitigating such voltage drops have relied on reactive measures to address voltage drops. For example, throttling mechanisms may reduce memory activity upon detecting a voltage drop. However, such reactive approaches inherently suffer from latency, as the voltage drop must occur and be detected before corrective action is taken. This delay can allow for transient instabilities, impacting the overall reliability and performance of the system.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of a computing system configured to dynamically adjust memory states based on the density of received CAS commands, in accordance with some implementations.

FIG. 2 is a block diagram of a memory controller configured to dynamically adjust memory states based on the density of received CAS commands, in accordance with some implementations.

FIGS. 3 and 4 illustrate an operational timeline of a memory subsystem during dynamic transitions between different memory states, in accordance with some implementations.

FIG. 5 is a flow diagram illustrating an operational routine for dynamically adjusting memory states based on the density of received CAS commands, in accordance with some implementations.

### DETAILED DESCRIPTION

Existing methods for managing memory bandwidth, such as software-controlled throttling, may not be suitable for addressing power stability concerns. These methods often rely on external control mechanisms, introducing overhead and complexity that can hinder their effectiveness in real-time, high-frequency environments. Consequently, there remains a need for techniques that can proactively manage memory bandwidth to ensure power stability without compromising system performance or reliability.

Implementations of techniques described herein provide systems and methods for proactively mitigating voltage drops during dynamic idle-to-active transitions in memory systems and/or subsystems. These techniques stabilize power consumption by controlling memory bandwidth via configurable throttling mechanisms, which dynamically adjust command flow to prevent sudden power surges while maintaining overall system reliability and performance.

Column Address Strobe (CAS) commands are a fundamental aspect of digital memory operation, facilitating the access of specific columns within a pre-selected row of a dynamic random-access memory (DRAM) module. CAS commands are issued by the system to retrieve or store data at specific memory locations, ensuring the timely availability of data for various computational tasks. As such, these commands are instrumental in maintaining efficient memory operation and enabling high-bandwidth performance.

The memory controller serves as an intermediary between the processor and the memory subsystem, and is responsible for interpreting memory access requests from the processor, translating those requests into appropriate CAS commands, and issuing those commands to the DRAM. Beyond command translation and issuance, the memory controller also ensures compliance with timing constraints and prioritization rules associated with memory operation. For instance, it manages the timing between successive CAS commands to adhere to memory specifications and optimize throughput.

In some implementations, the memory controller incorporates arbitration circuitry to manage concurrent access requests to the memory subsystem. The arbitration circuitry prioritizes and sequences these requests to prevent conflicts and ensure fair allocation of memory resources across multiple requestors. When coupled with command throttling mechanisms, such as those described in the context of dynamic idle-to-active transitions, the arbitration circuitry enforces bandwidth limits and manages command queuing. For example, during periods of CAS command throttling, the arbitration circuitry may selectively suppress or delay CAS commands to limit command density, mitigating the risk of power and/or voltage drops and maintaining system stability.

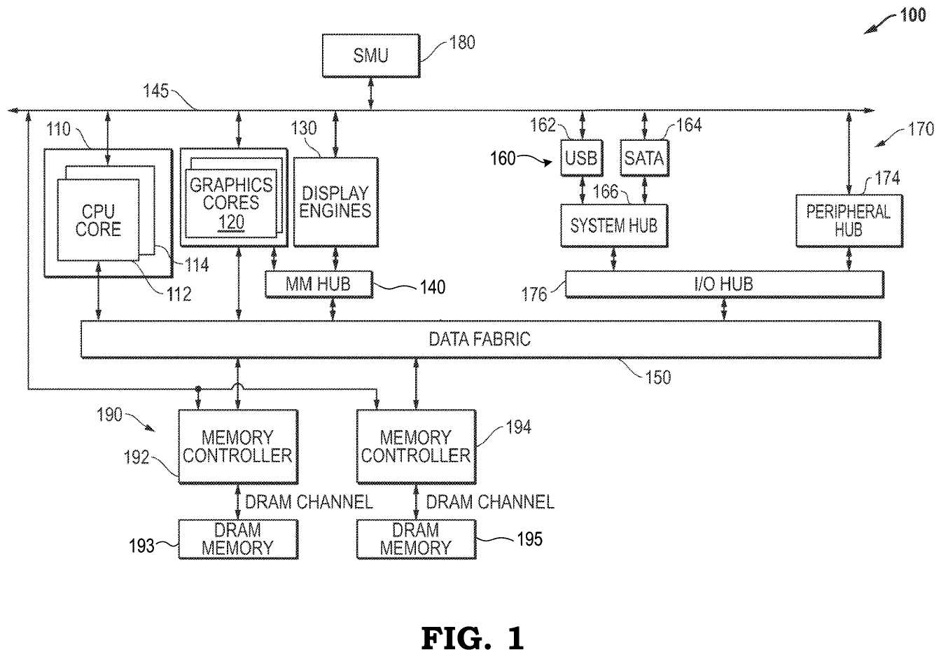

FIG. 1 is a block diagram of a computing system having one or more processors and memory subsystems, in accordance with some implementations. In the depicted implementation, an accelerated processing unit (APU) 100 is implemented as a System-on-Chip (SoC) which may be part of a variety of host data processing platforms. While an APU is shown in this implementation, other data processing platforms such as a central processing unit (CPU) or a graphics processing unit (GPU) may be used. APU 100 includes generally a CPU core complex 110, a graphics core 120, a set of display engines 130, a memory management hub 140, a data fabric 150, a set of peripheral controllers 160, a set of peripheral bus controllers 170, a system management unit (SMU) 180, and a set of memory controllers 192 and 194, each of which is respectively coupled to one of DRAM memories 193, 195.

In the depicted implementation, memory controllers 192 and 194 are respectively responsible for managing data access to the DRAM memories 193 and 195. In certain implementations, the memory controllers 192 and 194 monitor the density of received CAS commands within an idling window parameter to determine memory state transitions for the DRAM memories 193 and 195. In particular, and as described in greater detail elsewhere herein, arbitration circuitry within the memory controllers 192 and 194 tracks CAS command activity and, based on one or more configurable parameters, selectively throttles CAS command execution when transitioning from an idle state to a throttled state. During such throttling, the memory controllers 192 and 194 enforce bandwidth restrictions by delaying or masking CAS commands directed to the DRAM memories 193 and 195, mitigating power drops associated with idle-to-active memory state transitions. Once throttling completes, the memory controllers 192 and 194 resume full-speed command processing, ensuring efficient and stable memory operation while dynamically adapting to workload variations.

CPU core complex 110 includes a CPU core 112 and a CPU core 114. In this example, CPU core complex 110 includes two CPU cores, but in other implementations CPU core complex 110 can include an arbitrary number of CPU cores. Each of CPU cores 112 and 114 is bidirectionally connected to a system management network (SMN) 145, which forms a control fabric, and to data fabric 150, and is capable of providing memory access requests to data fabric 150. Each of CPU cores 112 and 114 may be unitary cores or may further be a core complex with two or more unitary cores sharing certain resources such as caches.

In the depicted implementation, graphics core 120 is a graphics processing unit (GPU) capable of performing graphics operations such as vertex processing, fragment processing, shading, texture blending, and similar operations in a parallel manner. Graphics core 120 is bidirectionally connected to the SMN 145 and to data fabric 150 and is capable of providing memory access requests to data fabric 150. In this regard, APU 100 may either support a unified memory architecture in which CPU core complex 110 and graphics core 120 share the same memory space, or a memory architecture in which CPU core complex 110 and graphics core 120 share a portion of the memory space, while graphics core 120 also uses a private graphics memory not accessible by CPU core complex 110.

Display engines 130 render and rasterize objects generated by graphics core 120 for display on a monitor. Graphics core 120 and display engines 130 are bidirectionally connected to a common memory management hub 140 for uniform translation into appropriate addresses in memory, and memory management hub 140 is bidirectionally connected to data fabric 150 for generating such memory accesses and receiving read data returned from the memory system.

Data fabric 150 includes a crossbar switch for routing memory access requests and memory responses between any memory accessing agent and memory controllers 190. In certain implementations, the data fabric 150 also includes a system memory map, defined by a basic input/output system (BIOS), for determining destinations of memory accesses based on the system configuration, as well as buffers for each virtual connection.

Peripheral controllers 160 include a USB controller 162 and a serial advanced technology attachment (SATA) interface controller 164, each of which is bidirectionally connected to a system hub 166 and to SMN 145. These two controllers are merely exemplary of peripheral controllers that may be used in APU 100. Peripheral bus controllers 170 include a peripheral controller hub 174 that is bidirectionally connected to an input/output (I/O) hub 176 and to SMN 145. I/O hub 176 is bidirectionally connected to system hub 166 and to data fabric 150. Thus, for example, a CPU core can program registers in USB controller 162, SATA interface controller 164, or peripheral controller hub 174 through by accessing data fabric 150 via I/O hub 176.

Also in the depicted implementation, SMU 180 is a local controller that controls the operation of the resources on APU 100 and synchronizes communication among them. The SMU 180 manages power-up sequencing of the various processors on APU 100 and controls multiple off-chip devices via reset, enable and other signals. The SMU 180 also manages power for the various processors and other functional blocks.

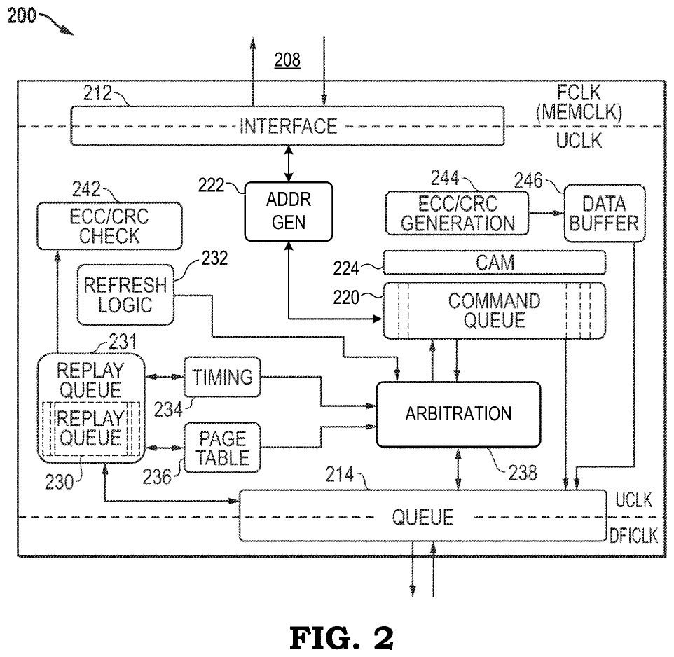

FIG. 2 is a block diagram of a memory controller 200 in accordance with some implementations. Memory controller 200 includes an interface 212, a memory interface queue 214, a command queue 220, an address generator 222, a content addressable memory (CAM) 224, replay control logic 231 including a replay queue 230, refresh control logic 232, a timing block 234, a page table 236, arbitration circuitry 238, error correction code (ECC) check circuitry 242, an ECC generation block 244, and a data buffer 246.

To facilitate mitigation of voltage drops during dynamic idle-to-active transitions in DRAM memory, in various implementations the command queue 220, arbitration circuitry 238, and refresh control logic 232 operate in coordination to regulate CAS command execution based on monitored command density. The command queue 220 stores received CAS commands before execution and provides a structured pipeline for prioritizing requests. Arbitration circuitry 238 manages command scheduling, determining whether CAS commands should be executed, delayed, or masked based on a configurable idling threshold parameter. During periods of increased CAS command density, the arbitration circuitry 238 enforces throttling by selectively blocking command issuance for a defined throttling duration, ensuring that memory activity ramps up in a controlled manner. Additionally, refresh control logic 232 maintains memory integrity by coordinating DRAM refresh cycles with command throttling, preventing excessive refresh-induced power fluctuations.

Interface 212 has a first bidirectional connection to data fabric over an external bus 208, and has an output. In the depicted implementation, the external bus 208 is compatible with the advanced extensible interface version four specified by ARM Holdings, PLC of Cambridge, England, known as “AXI4”, but can be other types of interfaces in other implementations. Interface 212 translates memory access requests from a first clock domain known as the FCLK (or MEMCLK) domain to a second clock domain internal to memory controller 200 known as the UCLK domain. Similarly, memory interface queue 214 provides memory access requests from the UCLK domain to a DFICLK domain associated with the DFI interface.

An address generator 222 decodes addresses of memory access requests received from the data fabric over the external bus 208. The memory access requests include access addresses in the physical address space represented in a normalized format. Address generator 222 converts the normalized addresses into a format that can be used to address the actual memory devices in the memory system, as well as to efficiently schedule related accesses. For example, in certain implementations this format includes a region identifier that associates the memory access request with a particular rank, a row address, a column address, a bank address, and a bank group. On startup, the system BIOS queries the memory devices in memory system to determine their size and configuration, and programs a set of configuration registers associated with address generator 222. Address generator 222 uses the configuration stored in the configuration registers to translate the normalized addresses into the appropriate format.

Command queue 220 is a queue of memory access requests received from the memory accessing agents in APU 100, such as CPU cores 112 and 114 and graphics core 120. Command queue 220 stores the address fields decoded by address generator 222 as well as other address information that allows arbitration circuitry 238 to select memory accesses efficiently, such as including (as non-limiting examples) access type and quality of service (QoS) identifiers. CAM 224 includes information to enforce ordering rules, such as write after write (WAW) and read after write (RAW) ordering rules. Command queue 220 is a stacked command queue including multiple entry stacks each containing multiple command entries, in this implementation 32 entry stacks of four entries each, as further described below.

Error correction code (ECC) generation block 244 determines the ECC of write data to be sent to the memory. This ECC data is then added to the write data in data buffer 246. ECC check circuitry 242 checks the received ECC against the incoming ECC.

Replay queue 230 is a temporary queue for storing selected memory accesses picked by arbitration circuitry 238 that are awaiting responses, such as address and command parity responses. Replay control logic 231 accesses ECC check circuitry 242 to determine whether the returned ECC is correct or indicates an error. Replay control logic 231 initiates and controls a replay sequence in which accesses are replayed in the case of a parity or ECC error of one of these cycles. Replayed commands are placed in the memory interface queue 214.

Refresh control logic 232 includes state machines for various powerdown, refresh, and termination resistance (ZQ) calibration cycles that are generated separately from normal read and write memory access requests received from memory accessing agents. For example, if a memory rank is in precharge powerdown, it must be periodically awakened to run refresh cycles. Refresh control logic 232 generates refresh commands periodically and in response to designated conditions to prevent data errors caused by leaking of charge off storage capacitors of memory cells in DRAM chips.

Arbitration circuitry 238 is bidirectionally connected to command queue 220 and performs intelligent scheduling of memory accesses to improve the usage of the memory bus. Arbitration circuitry 238 uses timing block 234 to enforce proper timing relationships by determining whether memory accesses in command queue 220 are eligible for issuance based on DRAM timing parameters. For example, each DRAM has a minimum specified time between activate commands, known as “tRc”. Timing block 234 maintains a set of counters that determine eligibility based on this and other timing parameters (e.g., timing parameters specified in the JEDEC specification), and is bidirectionally connected to replay queue 230. Page table 236 maintains state information about active pages in each bank and rank of the memory channel for arbitration circuitry 238, and is bidirectionally connected to replay queue 230. In certain implementations, arbitration circuitry 238 includes a single command input for each entry stack of command queue 220, and selects commands therefrom to schedule for dispatch through memory interface queue 214 to the DRAM channel.

In response to write memory access requests received from interface 212, ECC generation block 244 computes an ECC according to the write data. Data buffer 246 stores the write data and ECC for received memory access requests, and outputs the combined write data/ECC to memory interface queue 214 when arbitration circuitry 238 picks the corresponding write access for dispatch to the memory channel.

Memory controller 200 includes circuitry that allows it to pick memory accesses for dispatch to the associated memory channel. In order to make the desired arbitration decisions, address generator 222 decodes the address information into predecoded information including rank, row address, column address, bank address, and bank group in the memory system, and command queue 220 stores the predecoded information. Configuration registers (not shown) store configuration information to determine how address generator 222 decodes the received address information. Arbitration circuitry 238 uses the decoded address information, timing eligibility information indicated by timing block 234, and active page information indicated by page table 236 to efficiently schedule memory accesses while observing other criteria such as quality of service (QoS) requirements. For example, arbitration circuitry 238 implements a preference for accesses to open pages to avoid the overhead of precharge and activation commands required to change memory pages, and hides overhead accesses to one bank by interleaving them with read and write accesses to another bank. In particular during normal operation, arbitration circuitry 238 normally keeps pages open in different banks until they are required to be precharged prior to selecting a different page.

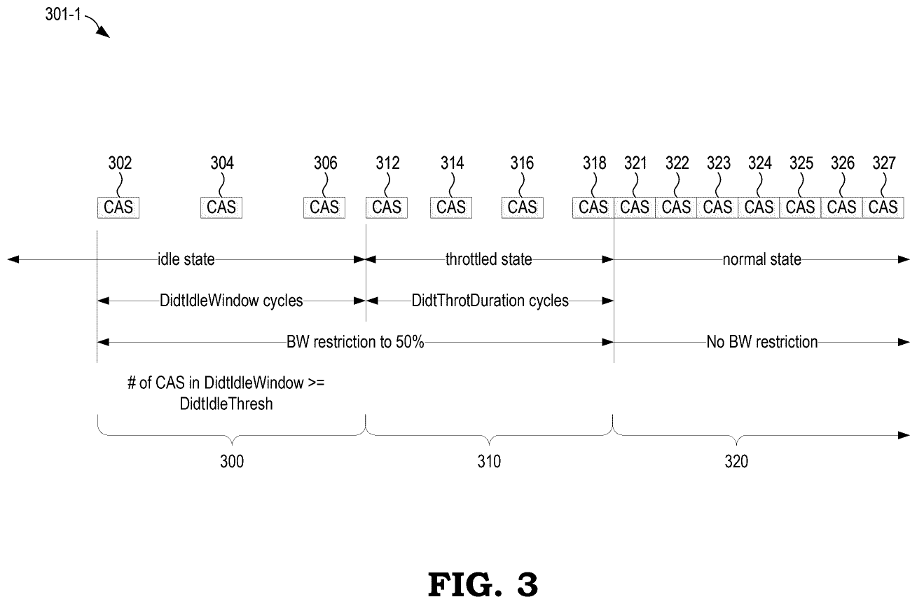

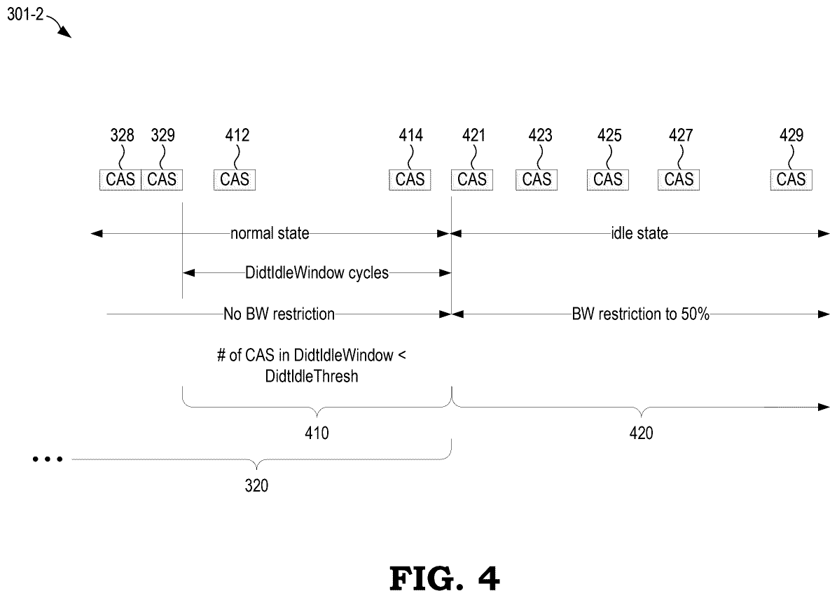

FIG. 3 illustrates an operational timeline 301 (which includes timeline 301-1 of FIG. 3 and continues through timeline 301-2 of FIG. 4) of a memory subsystem during dynamic transitions between different memory states, in accordance with some implementations. The timeline 301 represents a sequence of memory cycles during which the memory subsystem transitions from an idle state 300, through a throttled state 310, and into a normal memory state 320. The transitions are managed based on incoming CAS commands received by the memory controller (e.g., memory controller 200 of FIG. 2), such as the CAS commands 302, 304, 306, 312, 314, 316, 318, and subsequent commands 321-327, received during the illustrated memory cycles. As used herein, a memory cycle refers to a discrete unit of time during which a memory subsystem performs a specific operation or set of operations, such as reading data, writing data, refreshing memory cells, or issuing and executing commands like CAS commands (which in various scenarios and implementations include both read and write commands). The duration of a memory cycle is typically determined by the operating frequency of the memory clock and may vary depending on the type of memory, such as dynamic random-access memory (DRAM), and its associated timing parameters.

The arbitration circuitry 238 within the memory controller 200 monitors the quantity of CAS commands issued within a defined window of memory cycles, referred to as the DidtIdleWindow. This monitoring is facilitated by hardware counters and configuration registers (not shown) within the memory controller 200, which are used by the arbitration circuitry 238 to track the CAS command density. For example, in certain implementations the DidtIdleWindow parameter is stored in a register accessible to the arbitration circuitry 238, and its value defines the size of the window over which CAS commands are counted. In the depicted implementation, the idle state 300 corresponds to a memory state characterized by a relatively low density of incoming CAS commands 302, 304, and 306 received during this period—that is, the quantity of CAS commands during the DidtIdleWindow is lower than a defined threshold, herein referred to as the DidtIdleThresh parameter and also stored in a configuration register. When the quantity of CAS commands issued within the DidtIdleWindow exceeds that defined threshold, the arbitration circuitry 238 responds to the relative high density of CAS commands by initiating a transition to a throttled state 310.

During the throttled state 310, the arbitration circuitry 238 enforces a bandwidth restriction, limiting the execution of CAS commands, e.g., to 50% of the maximum command bandwidth. This restriction is achieved by selectively throttling CAS commands, such as by delaying or masking certain commands, as illustrated for CAS commands 312, 314, and 316. For example, in some implementations, throttled CAS commands are masked by temporarily preventing selected commands from leaving the command queue during throttled cycles, effectively pausing their execution. In other implementations, rather than issuing a CAS command to DRAM, the memory controller could insert a no-operation (NOP) command (or similar) in order to achieve an idle cycle. In certain implementations, throttled CAS commands are temporarily held in queue (such as via replay queue 230 and replay control logic 231) for execution during the next available unthrottled cycle. The throttled state 310 persists for a defined number of memory cycles, referred to as the DidtThrotDuration. This duration is tracked using a separate register accessible to the arbitration circuitry 238, allowing fine-tuned control over the throttling behavior. By managing the timing and density of CAS commands, the arbitration circuitry 238 mitigates the risk of power and/or voltage drops during transitions from idle to high-bandwidth operation.

Once the DidtThrotDuration elapses, the arbitration circuitry 238 transitions the memory subsystem to the normal memory state 320—that is, a memory state in which received CAS commands are not throttled. In this state, no bandwidth restrictions are applied, and CAS commands, such as commands 321-327, are executed without throttling delays. By dynamically adjusting the memory state and throttling behavior in response to the density of CAS commands, the arbitration circuitry 238 ensures stable operation while mitigating the risk of power and/or voltage drops associated with sudden surges in memory activity.

FIG. 4 continues the example of FIG. 3, illustrating an operational timeline 301-2 of memory subsystem operations, and in particular illustrates a transition from the normal memory state 320 into a subsequent idle memory state 420, in accordance with some implementations. The timeline 301-2 again represents memory cycles during which CAS commands are received by the memory subsystem.

In the depicted implementation, CAS commands 328 and 329 continue the series of unthrottled commands 321-327 from FIG. 3, received within the normal memory state 320. During the normal memory state 320, the arbitration circuitry 238 imposes no bandwidth restrictions, enabling the execution of all received CAS commands without throttling. The arbitration circuitry 238 within the memory controller 200 continues monitoring the density of CAS commands issued within a defined window of memory cycles, referred to as the DidtIdleWindow 410. In this instance, the number of CAS commands within the DidtIdleWindow 410 falls below the defined threshold, DidtIdleThresh, prompting the arbitration circuitry 238 to transition the memory system to the idle state 420.

Upon entering the idle state 420, the memory subsystem imposes a bandwidth restriction, capping the execution of CAS commands at, e.g., 50% of the maximum bandwidth. This restriction is enforced by the arbitration circuitry 238, which selectively throttles CAS commands, as illustrated by CAS commands 412, 414, 421, 423, 425, 427, and 429. These commands are issued with controlled timing to maintain system stability while avoiding power and/or voltage drops during low-density memory activity.

The transitions between the states depicted in FIG. 4 further demonstrate the dynamic adjustments performed by the memory subsystem in response to varying CAS command densities. By leveraging configurable parameters, such as DidtIdleWindow and DidtIdleThresh, stored in registers accessible to the arbitration circuitry 238, the memory controller 200 ensures stable operation across varying workloads while managing power demands effectively.

In various implementations, the idling window parameter (in the example of FIGS. 3-4, “DidtIdleWindow”) and idle threshold parameter (“DidtIdleThresh”) allow adjustments to the behavior of the memory controller 200 during transitions between operational states. DidtIdleWindow defines a configurable window of memory cycles within which the arbitration circuitry 238 monitors the number of received CAS commands. This idling window enables the memory controller 200 (via the arbitration circuitry 238) to evaluate CAS command density over a discrete period, allowing it to identify shifts in memory access patterns that might necessitate memory state transitions. DidtIdleThresh specifies a threshold quantity of CAS commands that, when exceeded within the idling window defined by DidtIdleWindow, triggers a transition from an idle memory state to a throttled memory state. These parameters operate in conjunction to provide dynamic adaptability to workload variations and system requirements.

For example, adjustments to the DidtIdleWindow parameter may be made to optimize sensitivity to different memory workloads. In systems experiencing rapid fluctuations between idle and high-bandwidth memory states, a shorter DidtIdleWindow may be employed to provide quicker detection of increased CAS command activity. Conversely, a longer DidtIdleWindow may be advantageous in workloads with gradual transitions, reducing the likelihood of unnecessary throttling caused by short-lived spikes in activity. By tailoring this parameter to workload characteristics, the system can balance responsiveness with stability.

The idling threshold (“DidtIdleThresh”) parameter may also be adjusted based on power and performance requirements of the memory controller 200 or incorporating system. For example, in certain implementations a lower DidtIdleThresh value might be used in power-constrained environments, triggering throttling more readily to minimize the risk of power and/or voltage drops during transitions. In contrast, a higher DidtIdleThresh value may be advantageous in performance-critical systems to minimize throttling and maximize throughput at a potential cost of increased power variation.

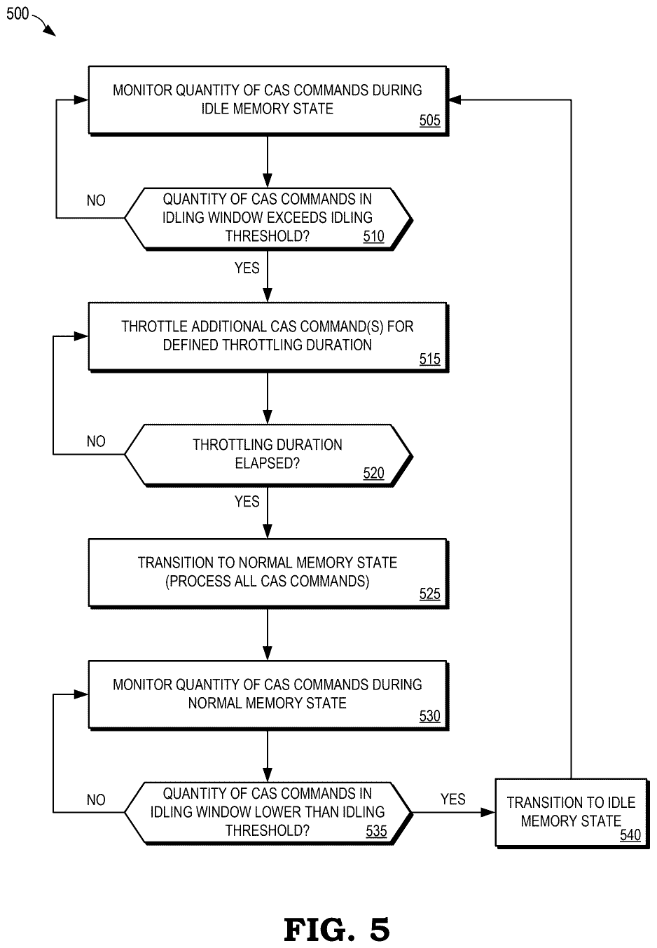

FIG. 5 is a flow diagram illustrating an operational routine 500 for dynamically adjusting memory states based on the density of received CAS commands, in accordance with some implementations. The operational routine 500 may be performed, for example, by a memory controller (e.g., memory controller 200 of FIG. 2) such as via arbitration circuitry (e.g., arbitration circuitry 238).

The routine 500 begins at block 505, in which the memory controller monitors the quantity of CAS commands received during an idle memory state. In certain implementations, this monitoring is performed over a configurable duration of memory cycles, referred to herein as the idling window, which is used to evaluate CAS command density. The routine proceeds to block 510.

At block 510, the memory controller determines whether the quantity of CAS commands received within the idling window exceeds a configurable idling threshold. If the quantity of CAS commands does not exceed the idling threshold, the routine returns to block 505 and continues to monitor the quantity of CAS commands during the idle memory state.

If in block 510 it was determined that the quantity of CAS commands during the idling window exceeds the idling threshold, the routine proceeds to block 515, in which additional received CAS commands are selectively throttled (such as by delaying and/or masking the CAS commands to be throttled) for a defined throttling duration. In certain implementations, such throttling is managed by arbitration circuitry within the memory controller, which enforces a bandwidth restriction such as limiting CAS command execution to 50% of maximum throughput. The routine 500 proceeds to decision block 520.

At decision block 520, the memory controller determines whether the throttling duration has elapsed. If the throttling duration has not elapsed, the routine returns to block 515, and additional CAS commands are managed according to the bandwidth restriction.

Once the throttling duration has elapsed, the routine proceeds to block 525, in which the memory controller transitions the memory subsystem to a normal memory state. In this normal memory state, all received CAS commands are processed as usual, without throttling. In certain implementations, this includes any backlog of CAS commands that have been delayed beyond the defined throttling duration. The routine proceeds to block 530.

At block 530, in the normal memory state, the memory controller continues to monitor the quantity of CAS commands received within the defined idling window. The routine proceeds to decision block 535.

At decision block 535, the memory controller determines whether the quantity of CAS commands within the idling window parameter has fallen below the defined idling threshold. If the CAS command density falls below this idling threshold, the routine proceeds to block 540, in which the memory controller transitions the memory subsystem back to the idle memory state, and then back to block 505. Otherwise, the system remains in the normal memory state, and the routine returns to block 530 for continued monitoring in the normal memory state.

In some implementations, the apparatus and techniques described above are implemented in a system including one or more integrated circuit (IC) devices (also referred to as integrated circuit packages or microchips), such as the computing system and memory subsystem(s) described above with reference to FIGS. 1-5. Electronic design automation (EDA) and computer aided design (CAD) software tools may be used in the design and fabrication of these IC devices. These design tools typically are represented as one or more software programs. The one or more software programs include code executable by a computer system to manipulate the computer system to operate on code representative of circuitry of one or more IC devices so as to perform at least a portion of a process to design or adapt a manufacturing system to fabricate the circuitry. This code can include instructions, data, or a combination of instructions and data. The software instructions representing a design tool or fabrication tool typically are stored in a computer readable storage medium accessible to the computing system. Likewise, the code representative of one or more phases of the design or fabrication of an IC device may be stored in and accessed from the same computer readable storage medium or a different computer readable storage medium.

A computer readable storage medium may include any non-transitory storage medium, or combination of non-transitory storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disk, magnetic tape, or magnetic hard drive), volatile memory (e.g., random access memory (RAM) or cache), non-volatile memory (e.g., read-only memory (ROM) or flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based flash memory), or coupled to the computer system via a wired or wireless network (e.g., network accessible storage (NAS)).

In some implementations, certain aspects of the techniques described above may implemented by one or more processors of a processing system executing software. The software includes one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

One or more of the elements described above is circuitry designed and configured to perform the corresponding operations described above. Such circuitry, in at least some implementations, is any one of, or a combination of, a hardcoded circuit (e.g., a corresponding portion of an application specific integrated circuit (ASIC) or a set of logic gates, storage elements, and other components selected and arranged to execute the ascribed operations), a programmable circuit (e.g., a corresponding portion of a field programmable gate array (FPGA) or programmable logic device (PLD)), or one or more processors executing software instructions that cause the one or more processors to implement the ascribed actions. In some implementations, the circuitry for a particular element is selected, arranged, and configured by one or more computer-implemented design tools. For example, in some implementations the sequence of operations for a particular element is defined in a specified computer language, such as a register transfer language, and a computer-implemented design tool selects, configures, and arranges the circuitry based on the defined sequence of operations.

Within this disclosure, in some cases, different entities (which are variously referred to as “components,” “units,” “devices,” “circuitry,” “engines,” “workgroups,” “launchers,” “interfaces,” “chiplets,” etc.) are described or claimed as “configured” to perform one or more tasks or operations. This formulation of “[entity] configured to [perform one or more tasks]” is used herein to refer to structure (e.g., a physical element, such as electronic circuitry, or an algorithm in software executed by such a physical element). More specifically, this formulation is used to indicate that this physical structure is arranged to perform the one or more tasks during operation. A structure can be said to be “configured to” perform some task even if the structure is not currently being operated. Thus, an entity described or recited as “configured to” perform some task refers to a physical element, such as a device, circuitry, memory storing program instructions executable to implement the task, or an algorithm executed using such a physical element. This phrase is not used herein to refer to something intangible. Further, the term “configured to” is not intended to mean “configurable to.” An unprogrammed field programmable gate array, for example, would not be considered to be “configured to” perform some specific function, although it could be “configurable to” perform that function after programming. Additionally, reciting in the appended claims that a structure is “configured to” perform one or more tasks is expressly intended not to be interpreted as having means-plus-function elements.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific implementations. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific implementations. However, the benefits, advantages, solutions to problems, and any feature(s) that may cause any benefit, advantage, or solution to occur or become more pronounced are not to be construed as a critical, required, or essential feature of any or all the claims. Moreover, the particular implementations disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular implementations disclosed above may be altered or modified and all such variations are considered within the scope of the disclosed subject matter. Accordingly, the protection sought herein is as set forth in the claims below.

What is claimed is:

1. A method comprising:
responsive to a quantity of Column Address Strobe (CAS) commands received at a memory controller exceeding a defined threshold during an idle first memory state of a memory communicatively coupled to the memory controller, throttling one or more additional CAS commands for a defined quantity of cycles; and
after the defined quantity of cycles, transitioning to a second memory state of the memory and discontinuing throttling received CAS commands.

2. The method of claim 1, wherein the idle first memory state of the memory is characterized by a quantity of CAS commands received during the idle first memory state being below the defined threshold.

3. The method of claim 1, wherein throttling the one or more additional CAS commands comprises selectively delaying execution of the one or more additional CAS commands.

4. The method of claim 1, wherein throttling one or more additional CAS commands comprises masking the one or more additional CAS commands for the defined quantity of cycles.

5. The method of claim 1, wherein one or more of the defined threshold and the defined quantity of cycles are configurable parameters, and wherein the method further comprises storing the one or more of the defined threshold and the defined quantity of cycles in registers of the memory controller.

6. The method of claim 5, further comprising configuring at least one of the one or more of the defined threshold and the defined quantity of cycles based on a power constraint of the memory.

7. The method of claim 1, wherein transitioning to the second memory state comprises processing a backlog of CAS commands accumulated during the defined quantity of cycles.

8. The method of claim 1, further comprising monitoring a density of received CAS commands during the second memory state and transitioning to the idle first memory state responsive to the density of received CAS commands falling below the defined threshold.

9. The method of claim 1, wherein the idle first memory state is characterized by a power consumption level below a defined power threshold.

10. The method of claim 1, wherein throttling one or more additional CAS commands comprises interleaving execution of the one or more additional CAS commands with one or more cycles without execution of the one or more additional CAS commands during the defined quantity of cycles.

11. A system comprising:
a memory;
a memory controller communicatively coupled to the memory, the memory controller comprising arbitration circuitry to:
responsive to a quantity of Column Address Strobe (CAS) commands received at the memory controller exceeding a defined threshold during an idle first memory state of the memory, throttle one or more additional CAS commands for a defined quantity of cycles; and
after the defined quantity of cycles, transition the memory to a second memory state and discontinue throttling received CAS commands.

12. The system of claim 11, wherein the idle first memory state of the memory is characterized by a quantity of CAS commands received during the idle first memory state being below the defined threshold.

13. The system of claim 11, wherein to throttle the one or more additional CAS commands comprises selectively delaying execution of the one or more additional CAS commands.

14. The system of claim 11, wherein to throttle one or more additional CAS commands comprises masking the one or more additional CAS commands for the defined quantity of cycles.

15. The system of claim 11, wherein one or more of the defined threshold and the defined quantity of cycles are configurable parameters, and wherein the system further comprises one or more registers of the memory controller to store the one or more of the defined threshold and the defined quantity of cycles.

16. The system of claim 15, wherein at least one of the one or more of the defined threshold and the defined quantity of cycles are configured based on a power constraint of the memory.

17. The system of claim 11, wherein to transition the memory to the second memory state comprises processing a backlog of CAS commands accumulated during the defined quantity of cycles.

18. The system of claim 11, wherein the arbitration circuitry is further to monitor a density of received CAS commands during the second memory state, and transition the memory to the idle first memory state responsive to the density of received CAS commands falling below the defined threshold.

19. A memory controller, the memory controller configured to:
responsive to a quantity of Column Address Strobe (CAS) commands received at the memory controller exceeding a defined threshold during an idle first memory state of a memory communicatively coupled to the memory controller, throttle one or more additional CAS commands for a defined quantity of cycles; and
subsequent to the defined quantity of cycles, transition the memory to a second memory state and discontinue throttling received CAS commands.

20. The memory controller of claim 19, wherein to throttle the one or more additional CAS commands comprises selectively delaying execution of the one or more additional CAS commands.
